(19) United States
(12) Patent Application Publication
(10) Pub. No.: US 2012/0081875 A1
(43) Pub. Date: Apr. 5, 2012

(54) ELECTRONIC DEVICE

(75) Inventors: Shingo YAMAGUCHI, Kawasaki (JP); Satoshi Watanabe, Kawasaki (JP); Yasuhiro Ite, Kawasaki (JP); Kohei Choraku, Kawasaki (JP)

(73) Assignee: Fujitsu Limited, Kawasaki (JP)

(21) Appl. No.: 13/211,403

(22) Filed: Aug. 17, 2011

(30) Foreign Application Priority Data
Sep. 30, 2010 (JP) 2010-220573

(51) Int. Cl. H05K 7/02

(52) U.S. Cl. 361/807

(57) ABSTRACT

An electronic device includes a case having an opening, an electronic part mounted in the case, a cover detachably attached to the case to close the opening, an annular seal part disposed on one of the case and the cover, the seal part being positioned between the case and the cover to enclose the opening, the seal part being filled with a liquid, and a pressing part that presses the seal part in a first direction parallel to a closing surface of the cover to expand the seal part in a second direction intersecting the closing surface of the cover so that the seal part presses another of the case and the cover.

### CROSS-REFERENCE TO RELATED APPLICATION

This application is based upon and claims the benefit of priority of the prior Japanese Patent Application No. 2010-220573, filed on Sep. 30, 2010, the entire contents of which are incorporated herein by reference.

### FIELD

The embodiment discussed herein is related to an electronic device that uses a cover to close an opening formed in its case.

### BACKGROUND

Mobile telephones, personal digital assistants (PDAs), and other mobile terminals may have a waterproof or dustproof gasket disposed around an opening formed in the case or disposed on a cover to be attached onto the opening so as to protect electronic parts incorporated in the case or a battery pack included in the case against moisture or dust (see Japanese Laid-open Patent Publication No. 11-25940, for example).

If the gasket is attached to a sliding cover, when the cover is attached to the case, the cover must be slid while the gasket is pressed against the case. This needs a large operational force to slide the cover from when the cover starts to be attached until the attachment is completed, because of friction between the case and the gasket.

Even if the gasket is attached to a non-sliding cover, such as a so-called rotary cover that is attached to the case by having a claw formed on the cover engage the case and then rotating the cover around the claw, a problem also occurs; an operation to attach the cover to the case is complex because the cover must be pressed against the case while the claw on the cover engages the case.

If, as described above, the operational force to slide the cover is large or the operation to attach the case is complex, the cover may not be completely attached. Then, the cover, which is assumed to have been completely attached, may come off later.

### SUMMARY

According to an aspect of an embodiment, an electronic device includes a case having an opening, an electronic part mounted in the case, a cover detachably attached to the case to close the opening, an annular seal part disposed on one of the case and the cover, the seal part being positioned between the case and the cover to enclose the opening, the seal part being filled with a liquid, and a pressing part that presses the seal part in a first direction parallel to a closing surface of the cover to expand the seal part in a second direction intersecting the closing surface of the cover so that the seal part presses another of the case and the cover.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of a mobile telephone according to a first embodiment.

FIG. 2 is a rear view of a lower case in the first embodiment.

FIG. 3 is an exploded perspective view of the lower case in the first embodiment, with a cover removed.

FIG. 4 is an exploded perspective view of the lower case in the first embodiment.

FIG. 5 is a rear view of an external case in the first embodiment.

FIG. 6 is a cross sectional view of a first projection in the first embodiment.

FIG. 7 is a cross sectional view of a second projection in the first embodiment.

FIG. 8 is an internal view of the cover in the first embodiment.

FIG. 9 is a cross sectional view of the cover in the first embodiment.

FIG. 10 is a schematic internal view of a seal part in the first embodiment.

FIG. 11 is a schematic exploded perspective view of the seal part in the first embodiment.

FIG. 12A is a cross sectional view of the lower case when the cover in the first embodiment starts to be attached, illustrating the entire lower case.

FIG. 12B is a cross sectional view of the lower case when the cover in the first embodiment starts to be attached, illustrating the elliptical area XIIB in FIG. 12A.

FIG. 13A is a cross sectional view of the lower case when the cover in the first embodiment has been attached, illustrating the entire lower case.

FIG. 13B is a cross sectional view of the lower case when the cover in the first embodiment has been attached, illustrating the elliptical area XIIIB in FIG. 13A.

FIG. 14A is a graph representing the relationship in the first embodiment between the amount of slide of the cover and the internal pressure of a circular space below the seal part.

FIG. 14B illustrates states in which the amount of slide of the cover changes in the first embodiment.

FIG. 15 is a graph representing an operational force applied to a cover in a comparative example and an operational force applied to the seal part in the first embodiment.

FIG. 16 is an exploded perspective view in which the cover is removed from the lower case in a second embodiment.

FIG. 17 is an internal view of the cover in the second embodiment.

FIG. 18 is a cross sectional view of the lower case when the cover in the second embodiment starts to be attached.

FIG. 19 is a cross sectional view of the lower case when the cover in the second embodiment has been attached.

FIG. 20 is a partial cross sectional view of the lower case in a third embodiment.

### DESCRIPTION OF EMBODIMENTS

### First Embodiment

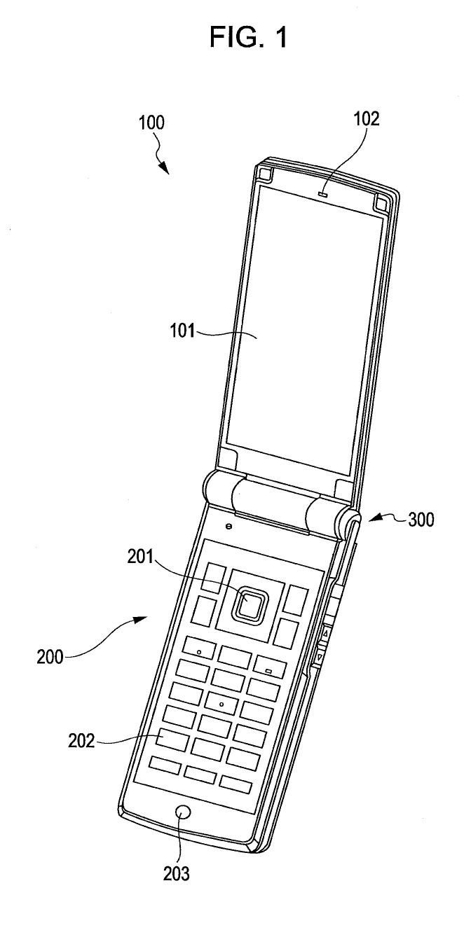

A first embodiment of the present disclosure will be described with reference to FIGS. 1 to 15.

Entire Structure of a Mobile Telephone

First, the entire structure of a mobile telephone will be described with reference to FIG. 1.

FIG. 1 is a perspective view of the mobile telephone according to the first embodiment.

As illustrated in FIG. 1, the mobile telephone includes an upper case 100, which is held by the user to his or her ear during a call, and a lower case 200, which is held by the user with a hand. The upper case 100 and lower case 200 are linked so as to be foldable around a hinge 300.

In the description that follows, the surfaces of the upper case 100 and lower case 200 that are hidden when the mobile telephone is folded will be referred to as the front surfaces and other surfaces that are exposed when the mobile telephone is folded will be referred to as the rear surfaces.

The upper case 100, which is shaped like a rectangular box, has a liquid crystal panel 101, on which menus and photographed images are displayed, and also includes an earpiece 102, from which sound is released from a speaker (not illustrated) mounted in the upper case 100.

The lower case 200, which is also shaped like a rectangular box, has on its surface a selection button 201 used to select various functions, pushbuttons 202 used to enter a telephone number and the like, and a mouthpiece 203 for transmitting sound such as voice to a microphone (not illustrated) mounted in the case.

Structure of the Lower Case 200

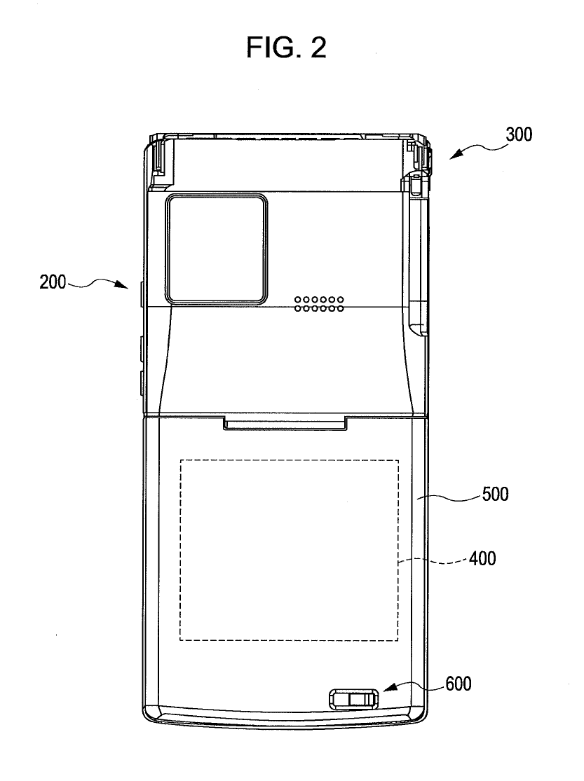

Next, the structure of the lower case 200 will be described with reference to FIGS. 2 to 5.

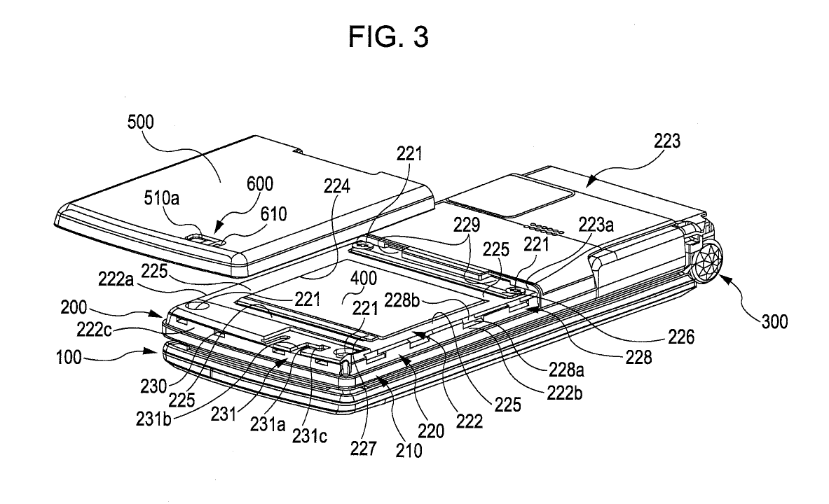

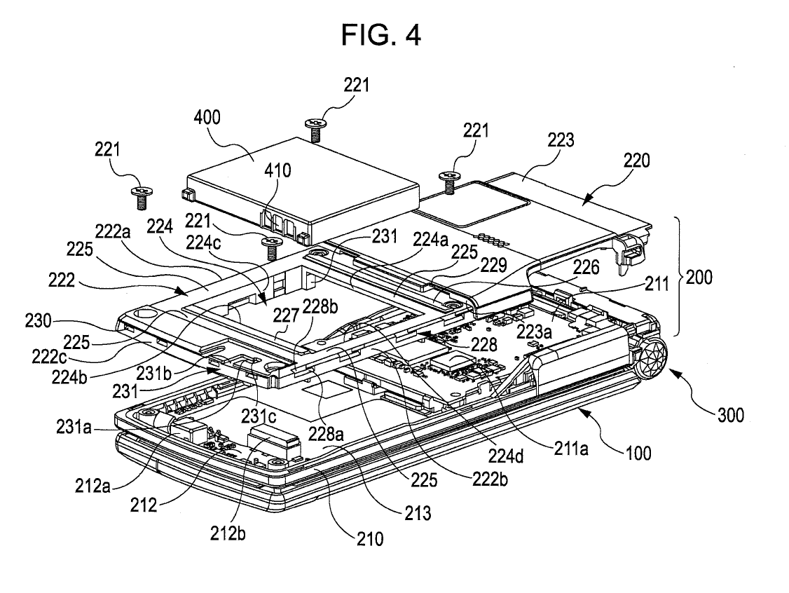

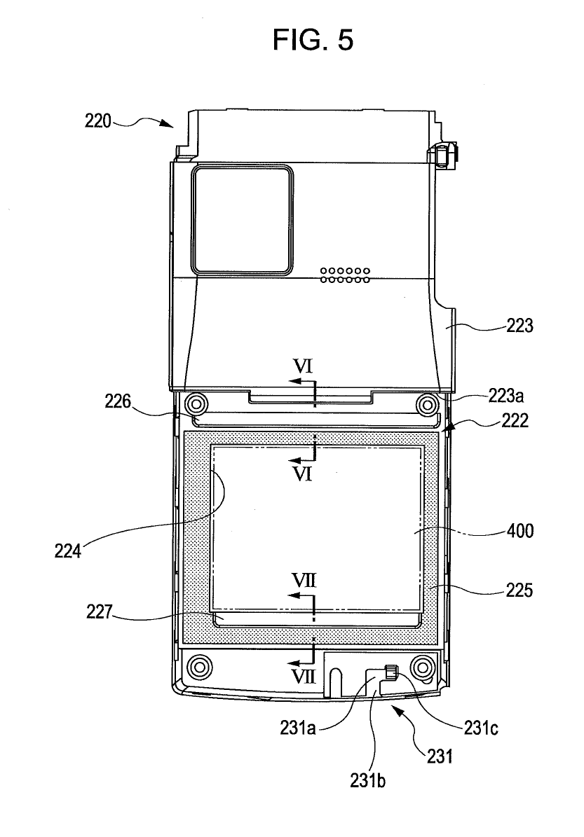

FIG. 2 is a rear view of the lower case 200 in the first embodiment, FIG. 3 is an exploded perspective view of the lower case 200 in the first embodiment, with a cover 500 removed, FIG. 4 is an exploded perspective view of the lower case 200 in the first embodiment, and FIG. 5 is a rear view of an external case 220 in the first embodiment.

As illustrated in FIGS. 2 and 3, the lower case 200, which is rectangular, has the cover 500 disposed opposite to the hinge 300, that is, at an end of the lower case 200 so as to cover a battery pack 400, and also includes a lock operation part 600, which locks the cover 500 attached to the lower case 200. The cover 500 is a so-called sliding cover; it is removably attached to the lower case 200. The lock operation part 600 prevents the cover 500 from coming off; it is provided as necessary.

As illustrated in FIG. 4, the lower case 200 has an internal case 210 linked to the hinge 300 and also includes an external case 220 disposed on the rear of the internal case 210, that is, opposite to the upper case 100. Both the internal case 210 and external case 220 are resin-molded parts and are single-piece parts. However, the internal case 210 and external case 220 may be formed by combining a plurality of parts.

In the internal case 210, shaped like a rectangular box, a first wiring board 211 is provided at a position near the hinge 300 and a second wiring board 212 is provided at a position away from the hinge 300. The first wiring board 211 and second wiring board 212 are secured to the internal case 210 by the use of a securing member (not illustrated) such as screws or double-sided tape. The first wiring board 211 and second wiring board 212 may be printed wiring boards, for example; a plurality of electronic parts 211a are mounted on the component side of the first wiring board 211 and a plurality of electronic parts 212a are mounted on the component side of the second wiring board 212, these electronic parts implementing various functions of the mobile telephone. A connector 212b, to which an electrode part 410 of the battery pack 400 is linked, is further mounted on the second wiring board 212. The internal case 210 has a battery mounting surface 213, which is used as the bottom of a battery case 224 (described later), at a position away from the hinge 300.

The external case 220 is attached to the internal case 210 by a plurality of screws 221. The external case 220 has a cover attaching part 222, to which the cover 500 is attached, at a position away from the hinge 300 and also has a decorated part 223, which is a decorated surface of the mobile telephone, at a position near the hinge 300. The cover attaching part 222 is formed so as to be lower than the decorated part 223 by an amount equal to the thickness of the cover 500, enabling the external case 220 and cover 500 to be flush with each other when the cover 500 is attached.

The cover attaching part 222 has the battery case 224 in which the battery pack 400 is accommodated, a pressurized wall part 225 pressed by a seal part 590 (described later) formed on the cover 500, a first projection 226 and a second projection 227 used to press the seal part 590, guide grooves 228 that guide a sliding claw 550 (described later) formed on the cover 500, first engaging holes 229 into which first engaging claws 570 (described later) formed on the cover 500 snap, second engaging holes 230 into which second engaging claws 580 (described later) formed on the cover 500 snap, and a lock groove 231 used to lock the lock operation part 600.

The battery case 224 is disposed at the center of the cover attaching part 222; it is shaped like a rectangular box to conform to the shape of the battery pack 400. The battery case 224 is defined by a first wall 224a to a fourth wall 224d, which correspond to the sides of the battery pack 400; the battery case 224 holds the battery pack 400 together with the cover 500.

The first wall 224a is disposed at a position near the hinge 300 of the battery case 224 and the second wall 224b is disposed at a position away from the hinge 300 of the battery case 224; these walls face each other and extend in the width direction of the lower case 200. The third wall 224c and fourth wall 224d are disposed at both ends of the width direction of the lower case 200 so as to face each other and extend in the longitudinal direction of the lower case 200. The depth of the battery case 224, that is, the distance from the battery mounting surface 213 of the internal case 210 to the pressurized wall part 225 is equal to the thickness of the battery pack 400. When the battery pack 400 is accommodated in the battery case 224, therefore, the height of the surface of the battery pack 400 is the same as the height of the pressurized wall part 225.

The first wall 224a has an insertion hole 231 at a position corresponding to the first wiring board 211. Therefore, the first wiring board 211 is exposed to the battery case 224 through the insertion hole 231. That is, the accommodation space above the first wiring board 211 communicates with the outside of the lower case 200 through the battery case 224.

The pressurized wall part 225 is a rectangular ring-shaped plane area disposed around the battery case 224, as indicated by the shaded area in FIG. 5; the pressurized wall part 225 extends parallel to the battery mounting surface 213. The pressurized wall part 225, linked to the first wall 224a to the fourth wall 224d of the battery case 224, form a so-called shoulder of the battery case 224. The pressurized wall part 225 has a larger width than a contact area 593b (described later) on an elastic film 593 of the seal part 590. Although the pressurized wall part 225 in this embodiment is formed as part of the external case 220, the surface of a rectangular ring-shaped plate pasted to the external case 220 may be used as the pressurized wall part 225, for example. Alternatively, the surface of another material, such as a resin, applied to the external case 220 may be used as the pressurized wall part 225.

The first projection 226 is disposed at a position away from the first wall 224a of the battery case 224 so as to be on the same side as the hinge 300 with respect to the first wall 224a. The pressurized wall part 225 described above is disposed between the first projection 226 and the battery case 224. That is, the first projection 226 is located at a position toward the hinge 300 with respect to the pressurized wall part 225, that is, at the front in a direction in which the cover 500 moves when it is attached.

The first projection 226 extends in the width direction of the lower case 200, across the width of the battery case 224. Although the first projection 226 in this embodiment is shaped like an elongated strip extending in the width direction of the lower case 200, the first projection 226 may be formed with a plurality of parts arranged in the width direction of the lower case 200, for example. Although the first projection 226 in this embodiment is disposed across the width of the battery case 224, the first projection 226 may be locally disposed in the width direction of the battery case 224, for example.

The second projection 227 is located at a position on the side opposite to the hinge 300 with respect to the second wall 224b of the battery case 224. The pressurized wall part 225 described above is disposed at the end of the second projection 227, opposite to the hinge 300, that is, on the same side as the end of the lower case 200. That is, the second projection 227 is located at a position toward the hinge 300 with respect to the pressurized wall part 225, that is, at the front in a direction in which the cover 500 moves when it is attached.

The second projection 227 extends in the width direction of the lower case 200, across the width of the battery case 224. Although the second projection 227 in this embodiment is shaped like an elongated strip extending in the width direction of the lower case 200, the second projection 227 may be formed with a plurality of parts arranged in the width direction of the lower case 200, for example. Although the second projection 227 in this embodiment is disposed across the width of the battery case 224, the second projection 227 may be locally disposed in the width direction of the battery case 224, for example.

The guide grooves 228 are disposed on a first side surface 222a and a second side surface 222b, located at both ends of the cover attaching part 222 in the width direction of the internal case 210, in the longitudinal direction of the lower case 200 with a prescribed spacing therebetween. Although, in this embodiment, four guide grooves 228 are provided, the number of guide grooves 228 may be one to three or five or more.

Each guide groove 228 has a first groove 228a and a second groove 228b. The first groove 228a extends parallel to the battery mounting surface 213, which is used as the bottom of the battery case 224. The second groove 228b is linked to an end of the first groove 228a, opposite to the hinge 300, and extends toward the back of the external case 220.

The second groove 228b guides a sliding claw 550 of the cover 500 into the first groove 228a. Each second groove 228b reaches the back of the external case 220. Therefore, the first groove 228 is exposed to the back of the external case 220 through the second groove 228b. The second groove 228b is located so that the contact area 593b on the elastic film 593 of the seal part 590 faces the pressurized wall part 225 while the sliding claw 550 of the cover 500 is guided into the first groove 228a.

Each first engaging hole 229 is formed at a position, on a joining wall 223a of the decorated part 223, that corresponds to the relevant first engaging claw 570 of the cover 500, and extends in the longitudinal direction of the lower case 200. Each second engaging hole 230 is formed at a position, on an end wall 222c of the cover attaching part 222, that corresponds to the relevant second engaging claw 580 of the cover 500, and extends in the longitudinal direction of the lower case 200. When the cover 500 is attached to the cover attaching part 222, therefore, the first engaging claws 570 and the second claws 580 of the cover 500 are respectively inserted into the first engaging holes 229 and the second engaging holes 230. Although, in this embodiment, two first engaging holes 229 and four second engaging holes 230 are formed, the present disclosure is not limited to this.

The lock groove 231 is disposed at a position, on the cover attaching part 222, opposite to the hinge 300. The lock groove 231 includes a first groove 231a extending in the width direction of the lower case 200 and a second groove 231b linked to an end of the first groove 231a and extending in a direction away from the hinge 300. The lock groove 231 further includes a holding part 231c linked to another end of the first groove 231a, which is opposite to the end to which the second groove 231b is linked. The holding part 231c is deeper than the first groove 231a and second groove 231b. When a locking part 620 (described later) formed on the cover 500 reaches the holding part 231c, therefore, the locking part 620 drops in the holding part 231c and held there.

Detailed Structures of the First Projection 226 and Second Projection 227

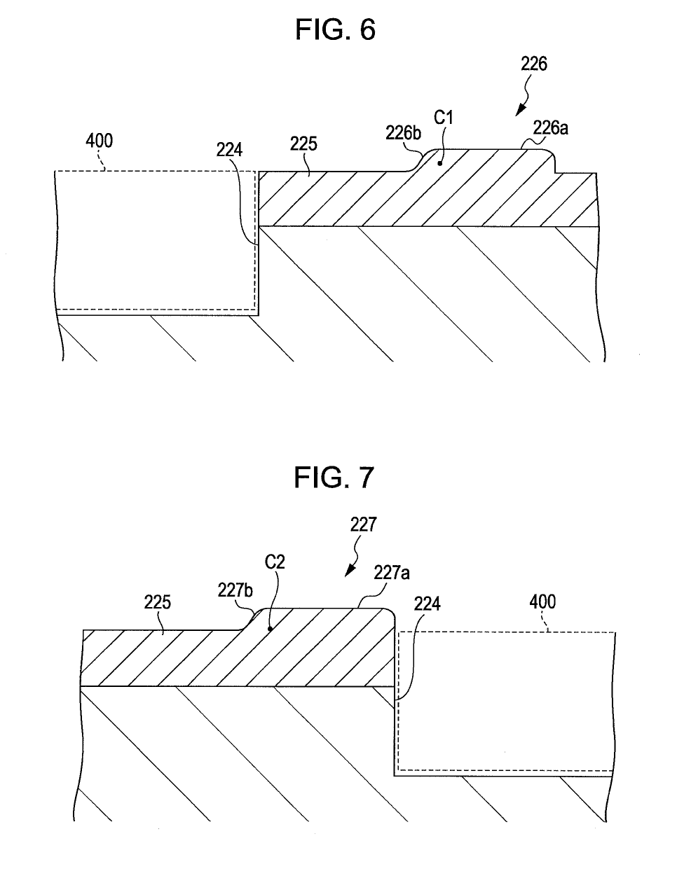

Next, the detailed structures of the first projection 226 and second projection 227 will be described with reference to FIGS. 6 and 7.

FIG. 6 is a cross sectional view of the first projection 226 in the first embodiment, illustrating section VI-VI in FIG. 5. FIG. 7 is a cross sectional view of the second projection 227 in the first embodiment, illustrating section VII-VII in FIG. 5.

As illustrated in FIG. 6, the first projection 226 has a plane 226a extending parallel to the pressurized wall part 225 and a curved surface 226b linking the pressurized wall part 225 and plane 226a. The height of the first projection 226, that is, the dimension from the pressurized wall part 225 to the plane 226a is determined depending on the height of the seal part 590, as described below. The curved surface 226b is an arc surface having a curvature center C1 near the surface of the lower case 200 (below the surface in the drawing); the curved surface 226b continuously, that is, smoothly links the pressurized wall part 225 and plane 226a. When the cover 500 is moved toward the hinge 300, therefore, the seal part 590 (described later) smoothly rides on the first projection 226, preventing the seal part 590 from being damaged during the attachment of the cover 500.

As illustrated in FIG. 7, the second projection 227 has a plane 227a extending parallel to the pressurized wall part 225 and a curved surface 227b linking the pressurized wall part 225 and plane 227a. The height of the second projection 227, that is, the dimension from the pressurized wall part 225 to the plane 227a is determined depending on the height of the seal part 590, as described below. The curved surface 227b is an arc surface having a curvature center C2 near the surface of the lower case 200 (below the surface in the drawing); the curved surface 227b continuously, that is, smoothly links the pressurized wall part 225 and plane 227a. When the cover 500 is moved toward the hinge 300, therefore, the seal part 590 (described later) smoothly rides on the second projection 227, preventing the seal part 590 from being damaged during the attachment of the cover 500.

Structure of the Cover 500

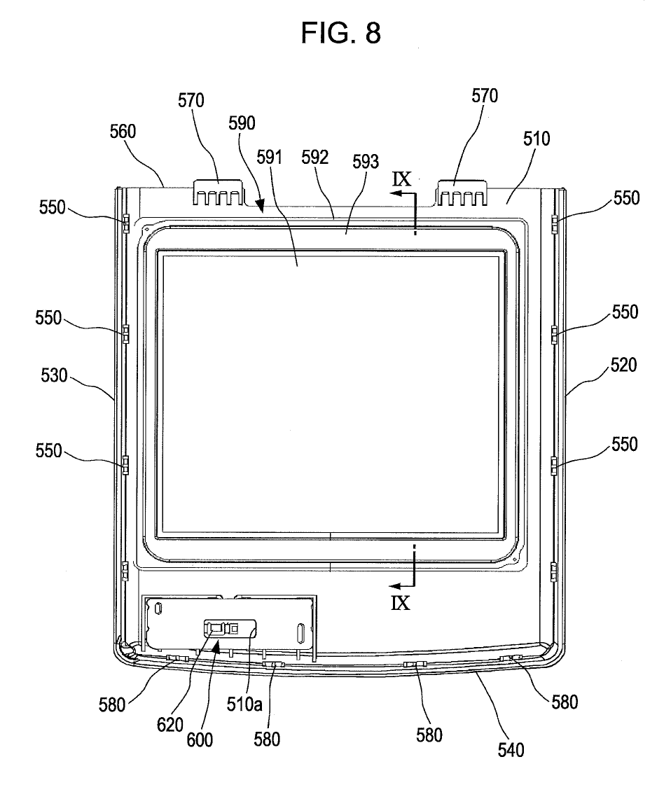

Next, the structure of the cover 500 will be described with reference to FIG. 8.

FIG. 8 is an internal view of the cover 500 in the first embodiment.

As illustrated in FIG. 8, the cover 500 has a flat plate 510 facing the battery pack 400 accommodated in the battery case 224, a first side plate 520 facing the first side surface 222a of the cover attaching part 222, a second side plate 530 facing the second side surface 222b of the cover attaching part 222, and a rear plate 540 facing the end wall 222c of the cover attaching part 222.

The flat plate 510, formed in a rectangular shape, has an elongated hole 510a extending in the width direction of the cover 500 at a position that is away from the hinge 300 when the cover 500 is attached to the cover attaching part 222. The elongated hole 510a passes through the cover 500, and has the lock operation part 600 on its internal surface.

The flat plate 510 further has a joint end 560, joined to the joining wall 223a of the decorated part 223, at a position away from the rear plate 540, and also has the first engaging claws 570 at positions corresponding to the first engaging holes 229 in the lower case 200. Each first engaging claw 570 is liked to the internal surface of the flat plate 510 and extends parallel to the flat plate 510 of the cover 500.

The first side plate 520 and second side plate 530 extend in a direction intersecting the flat plate 510, and each of them has one sliding claw 550 at a position corresponding to the relevant guide groove 228 of the cover attaching part 222. The sliding claws 550 are linked to the internal surfaces of the first side plate 520 and second side plate 530 and extend parallel to the flat plate 510 of the cover 500.

The rear plate 540 extends in a direction intersecting the flat plate 510 and has the second engaging claws 580 at positions corresponding to second engaging holes 230 in the cover attaching part 222. The second engaging claws 580 are linked to the internal surface of the cover 500 and extend toward the joint end 560.

Structure of the Lock Operation Part 600

Next, the structure of the lock operation part 600 will be described with reference to FIGS. 3 and 8.

As illustrated in FIGS. 3 and 8, the lock operation part 600 is movably disposed inside the elongated hole 510a in the cover 500 in the longitudinal direction of the elongated hole 510a, that is, in the width direction of the cover 500. The lock operation part 600 has a knob 610 disposed outside the cover 500 and the locking part 620 disposed inside the cover 500. The locking part 620 is disposed so that it is located inside the first groove 231a of the lock groove 231 when the cover 500 is attached to the cover attaching part 222. When the user moves the knob 610 in the longitudinal direction of the elongated hole 510a, therefore, the locking part 620 moves within the first groove 231a of the lock groove 231 together with the knob 610.

Structure of the Seal Part 590

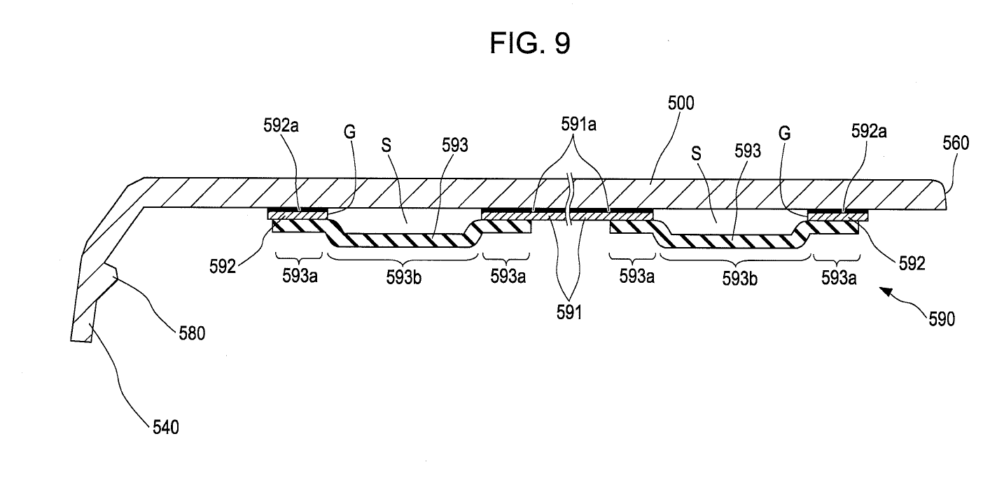

Next, the structure of the seal part 590 will be described with reference to FIGS. 9 to 11.

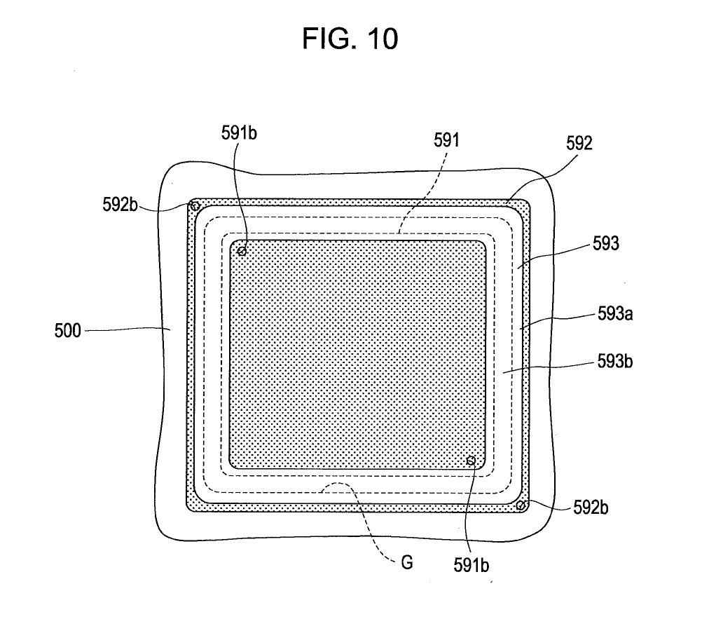

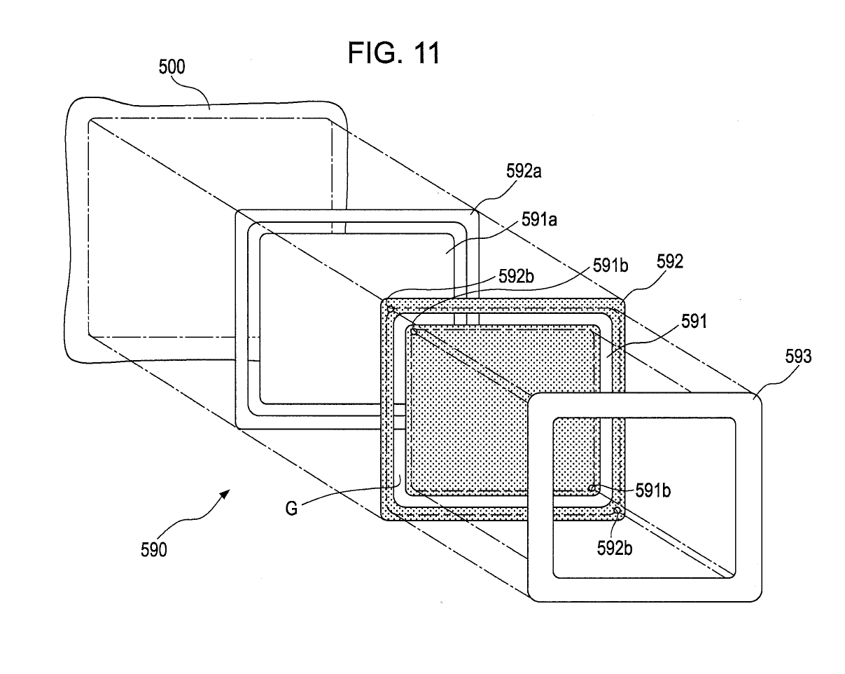

FIG. 9 is a cross sectional view of the cover 500 in the first embodiment, illustrating section IX-IX in FIG. 8. FIG. 10 is a schematic internal view of the seal part 590 in the first embodiment. FIG. 11 is a schematic exploded perspective view of the seal part 590 in the first embodiment.

As illustrated in FIGS. 9 to 11, the seal part 590, disposed inside the cover 500, has a first plate 591, a second plate 592, and an elastic film 593.

The first plate 591, which has a rectangular shape, is bonded to the internal surface of the cover 500 with an adhesive 591a. The second plate 592, which is shaped like a rectangular frame, is bonded to the internal surface of the cover 500 with an adhesive 592a. Although there is no limitation on the adhesive 591a and adhesive 592a, a Cemedine adhesive, a form tape, or the like is used. An olefin-based material may be used as a form, for example. The first plate 591 and second plate 592 respectively have a pin hole 591b and a pin hole 592b, which are used for positioning in the manufacturing of the seal part 590, at predetermined positions.

The second plate 592 is disposed around the first plate 591, an annular gap G being formed between the first plate 591 and the second plate 592. The annular gap G formed between the first plate 591 and the second plate 592 has a uniform dimension over the entire circumference. The gap corresponds to the pressurized wall part 225 when the cover 500 is attached to the cover attaching part 222. When the cover 500 is attached to the cover attaching part 222, therefore, the annular gap G encloses the battery case 224.

The elastic film 593, which is rectangular ring-shaped, is bonded to both the first plate 591 and the second plate 592. That is, the inner edges of the elastic film 593 are bonded to the surface of the first plate 591 around the entire circumference, and the outer edges of the elastic film 593 are bonded to the surface of the second plate 592 around the entire circumference. Accordingly, the elastic film 593 is secured to the cover 500 through the first plate 591 and second plate 592. Although there is no limitation on the material of the elastic film 593, any material that can follow fine recesses and protrusions present on the pressurized wall part 225 can be used; for example, rubber materials such as silicone rubber, nitrile rubber, and terpolymer (FPDM) of ethylene, propylene, or unconjugated dienemay be used. Alternately, elastomer materials may be used. The thickness of the elastic film 593 is, for example, 0.1 mm to 1.0 mm; if the elastic film 593 is made of a rubber material, however, the thickness is, for example, 0.2 mm to 0.5 mm; if the elastic film 593 is made of an erastomer material, the thickness is, for example, 0.5 mm to 0.7 mm. The elastic film 593 is bonded by, for example, primer to the first plate 591 and second plate 592. There is no limitation on the material of primer; a material suitable to the material of the elastic film 593 and to the materials of the first plate 591 and second plate 592 can be selected.

The elastic film 593 has a bonded area 593a bonded to the first plate 591 and second plate 592, and also has a contact area 593b, which is disposed so as to face the annular gap G and is brought into tight contact with the pressurized wall part 225 when the cover 500 is attached to the cover attaching part 222. The width of the contact area 593b is larger than the dimension of the gap G between the first plate 591 and the second plate 592. Therefore, the contact area 593b is slackened in a direction away from the cover 500, with respect to the surfaces of the first plate 591 and second plate 592. An annular space S is formed between the cover 500 and the elastic film 593. The annular space S is sealed by the cover 500, adhesive 591a, adhesive 592a, first plate 591, second plate 592, and elastic film 593, and includes air at a pressure equal to or slightly higher than atmospheric pressure. Even if the cover 500 is disposed so that the seal part 590 faces upward, therefore, the pressure of the air included in the annular space S enables the contact area 593b of the elastic film 593 to maintain the state protruding from the first plate 591 and second plate 592.

The contact area 593b of the elastic film 593 is disposed so that it corresponds to the pressurized wall part 225 when the cover 500 is attached to the cover attaching part 222. When the cover 500 is attached to the cover attaching part 222, therefore, the contact area 593b of the elastic film 593 is disposed so as to enclose the battery case 224.

The height of the seal part 590, that is, the height of the elastic film 593 with respect to the internal surface of the cover 500 is larger than the interval between the cover 500 and the first projection 226 or second projection 227 and is smaller than the intervals between the cover 500 and the pressurized wall part 225. When the sliding claw 550 of the cover 500 is positioned at the end, away from the hinge 300, of the first groove 228a of the guide groove 228, therefore, the elastic film 593 of the seal part 590 is separated from the lower case 200 (specifically, from the pressurized wall part 225). When the cover 500 is moved toward the hinge 300, the elastic film 593 of the seal part 590 comes into contact with the lower case 200 (specifically, with the first projection 226 and second projection 227).

An integral molding method is used as an exemplary method of manufacturing the seal part 590. When an integral molding method is used, the first plate 591 and second plate 592 are located at predetermined positions in the mold and the material of the elastic film 593 is poured into a cavity. At that time, primer may be applied to the surfaces of the first plate 591 and second plate 592, as necessary. When the material of the elastic film 593 is thermally cured, the elastic film 593 is bonded to the first plate 591 and second plate 592. At that time, pins provided in the mold may be inserted into the pin holes 591b and 592b formed in the first plate 591 and second plate 592 to position the first plate 591 and second plate 592. The first plate 591 and second plate 592, to which the elastic film 593 is bonded, is then bonded to the internal surface of the cover 500 with the adhesive 591a and adhesive 592a.

The method of manufacturing the seal part 590 is not limited to the above method; for example, the seal part 590 may be manually formed by preparing the cover 500, elastic film 593, first plate 591, second plate 592, adhesive 591a, adhesive 592a, primer, and the like.

Operation for Attaching the Cover 500

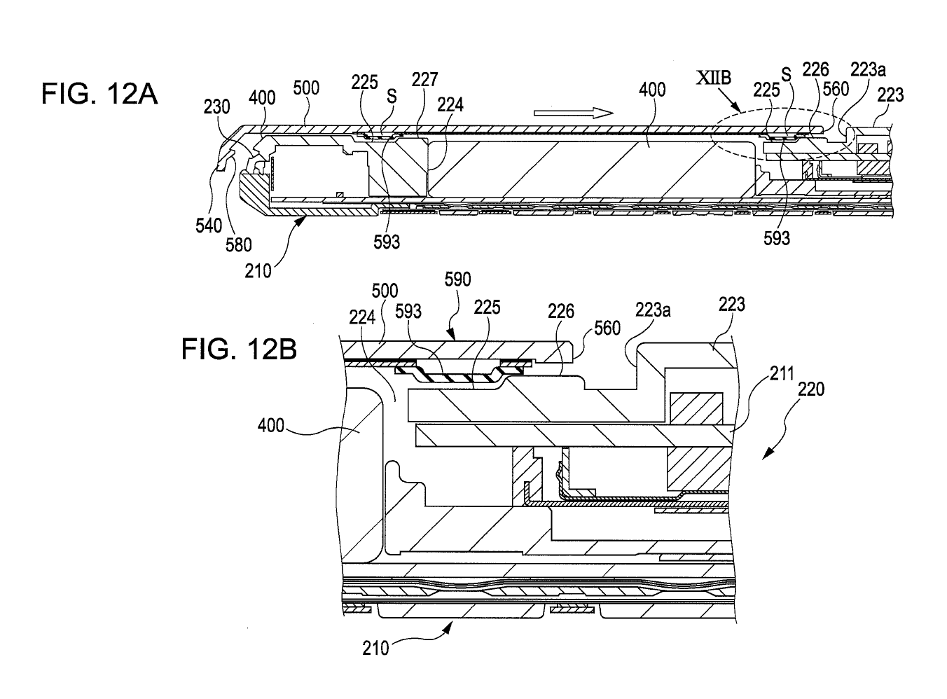

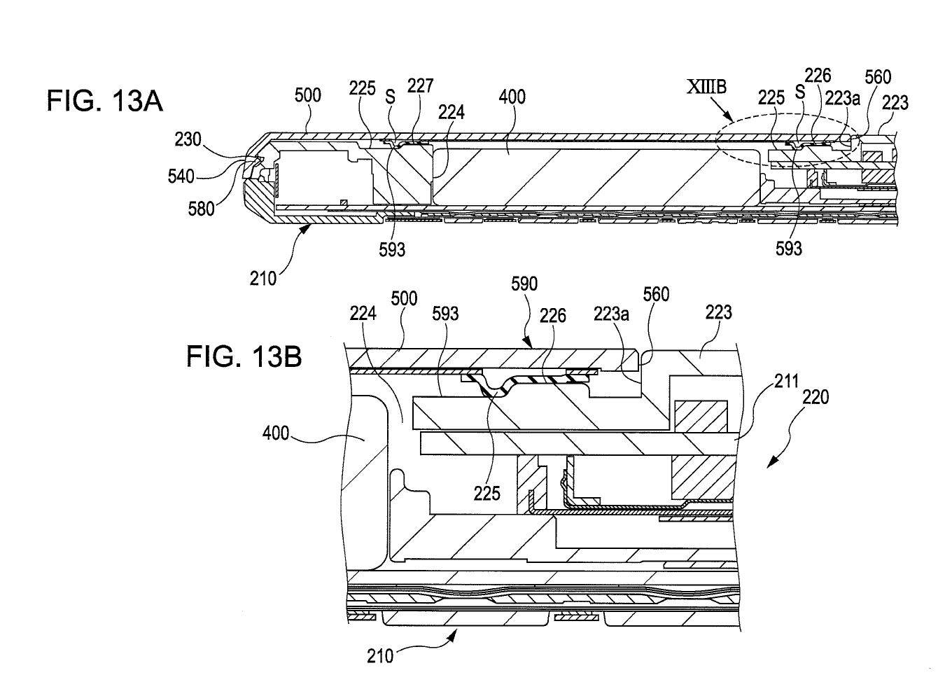

Next, attachment of the cover 500 will be described with reference to FIGS. 12A, 12B, 13A, and 13B.

FIG. 12A is a cross sectional view of the lower case 200 when the cover 500 in the first embodiment starts to be attached, illustrating the entire lower case 200. FIG. 12B is a cross sectional view of the lower case 200 when the cover 500 in the first embodiment starts to be attached, illustrating the elliptical area XIIB in FIG. 12A. FIG. 13A is a cross sectional view of the lower case 200 when the cover 500 in the first embodiment has been attached, illustrating the entire lower case 200. FIG. 13B is a cross sectional view of the lower case 200 when the cover 500 in the first embodiment has been attached, illustrating the elliptical area XIIIB in FIG. 13A.

When the cover 500 is attached to the cover attaching part 222, the sliding claws 550 of the cover 500 are first inserted into the second grooves 228b of the guide grooves 228 formed in the cover attaching part 222 and then the cover 500 is brought close to the cover attaching part 222. At that time, the contact area 593b, formed on the cover 500, of the elastic film 593 on the seal part 590 is located above the pressurized wall part 225 of the lower case 200. That is, the contact area 593b of the elastic film 593 formed on the seal part 590 is disposed at a position deviated from the first projection 226 and second projection 227. When the cover 500 is brought close to the cover attaching part 222, therefore, the seal part 590 does not come into contact with the first projection 226 and second projection 227.

When the sliding claws 550 of the cover 500 reach the first groove 228a of the guide groove 228, the cover 500 is moved toward the hinge 300. At that time, the seal part 590 formed on the cover 500 is not in contact with the lower case 200. Accordingly, the cover 500 can be simply moved just by applying a slight operational force to the cover 500.

When the seal part 590 reaches the first projection 226 and second projection 227, the cover 500 is further moved toward the hinge 300. The elastic film 593 of the seal part 590 then rides on the first projection 226 and second projection 227 and moves toward the hinge 300 together with the cover 500. At that time, the elastic film 593 of the seal part 590 is pressed by the first projection 226 and second projection 227 in a direction opposite to the movement direction of the cover 500, increasing the internal pressure of the annular space S below the seal part 590. The internal pressure of the annular space S expands the elastic film 593 of the seal part 590 toward the lower case 200, and the contact area 593b of the elastic film 593 is pressed by the pressurized wall part 225 of the lower case 200. Since, at that time, the annular space S below the seal part 590 is filled with the air, the internal pressure of the annular space S is increased over the entire length of the seal part 590. Therefore, the elastic film 593 of the seal part 590 is pressed by the pressurized wall part 225, not only in the vicinity of the first projection 226 and second projection 227 but also over the entire length of the seal part 590. Accordingly, the entire circumference of the battery case 224 is sealed by the seal part 590, achieving reliable protection from water and dust.

When the first engaging claws 570 and second engaging claws 580 of the cover 500 are respectively inserted into the first engaging hole 229 and second engaging hole 230 in the cover attaching part 222 and then the joint end 560 of the cover 500 abuts the joining wall 223a of the decorated part 223 of the lower case 200, the knob 610 of the lock operation part 600 is slid so as to drop the locking part 620 of the lock operation part 600 into the holding part 231c of the lock groove 231. This completes the operation to attach the cover 500.

As described above, in this embodiment, the seal part 590 is pressed by the first projection 226 and second projection 227 immediately before the cover 500 is completely attached, that is, immediately before the joint end 560 of the cover 500 abuts the joining wall 223a of the decorated part 223, only after which the elastic film 593 of the seal part 590 is pressed by the pressurized wall part 225. Accordingly, an operational force applied to the cover 500, which is needed until the seal part 590 reaches the first projection 226 and second projection 227, can be reduced.

In addition, even when the seal part 590 has reached the first projection 226 and second projection 227, the pressure of the elastic film 593 is not immediately increased, but is gradually increased as the internal pressure of the annular space S below the seal part 590 increases. Accordingly, another operational force applied to the cover 500, which is needed from when the seal part 590 has reached the first projection 226 and second projection 227 until the cover 500 is completely attached, can also be reduced.

Internal Pressure of the Annular Space S Below the Seal Part 590

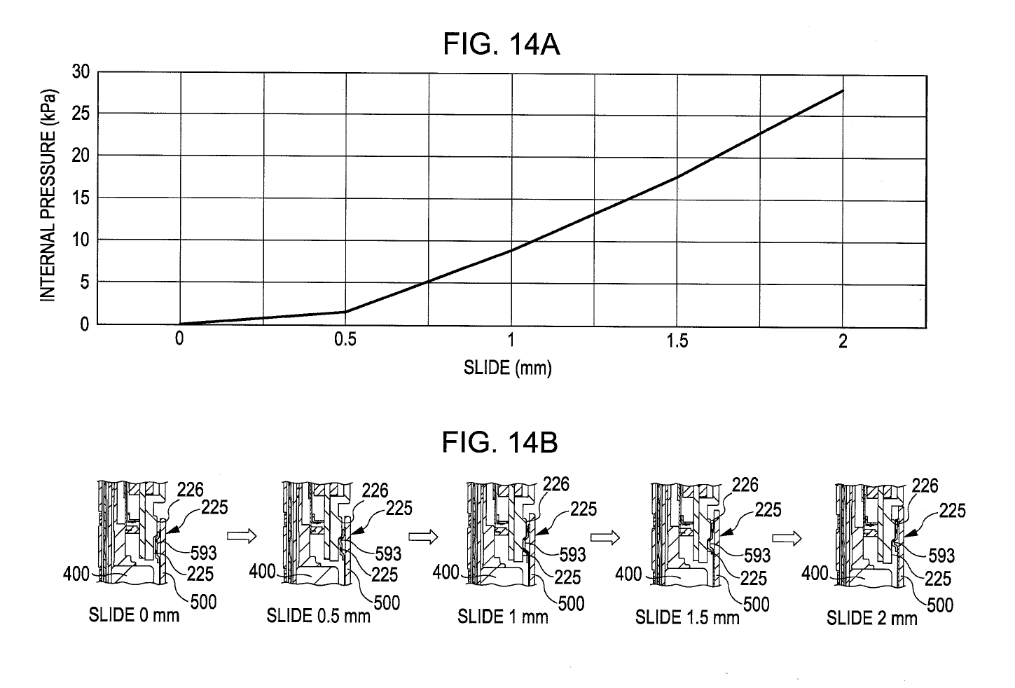

The internal pressure of the annual space S below the seal part 590 changes when the cover 500 is attached. This change will be described below with reference to FIGS. 14A and 14B.

FIG. 14A is a graph representing the relation in the first embodiment between the amount of slide of the cover 500 and the internal pressure of the circular space S below the seal part 590. The graph represents the amount of slide of the cover 500 on the horizontal axis; the origin (0 mm) of the graph represents the amount of slide of the cover 500 when the elastic film 593 of the seal part 590 has reached the first projection 226, and the end point (2 mm) of the graph represents the amount of slide of the cover 500 when the joint end 560 of the cover 500 has abutted the joining wall 223a of the decorated part 223. Accordingly, the left side of the graph is an area that extends until the elastic film 593 of the seal part 590 comes into contact with the first projection 226. FIG. 14B illustrates states in which the amount of slide of the cover 500 changes in the first embodiment. To simplify the description that follows, the second projection 227 is omitted in the drawing.

As illustrated in FIGS. 14A and 14B, the internal pressure of the annular space S remains at about 0 kPa until the elastic film 593 of the seal part 590 comes into contact with the first projection 226; after the elastic film 593 of the seal part 590 has reached the first projection 226, however, the internal pressure of the annular space S increases as the cover 500 is moved toward the hinge 300. When the amount of slide reaches 2 mm, that is, the joint end 560 of the cover 500 abuts the joining wall 223a of the decorated part 223, the internal pressure of the annular space S rises to about 28 kPa.

Operational Force Applied to the Cover

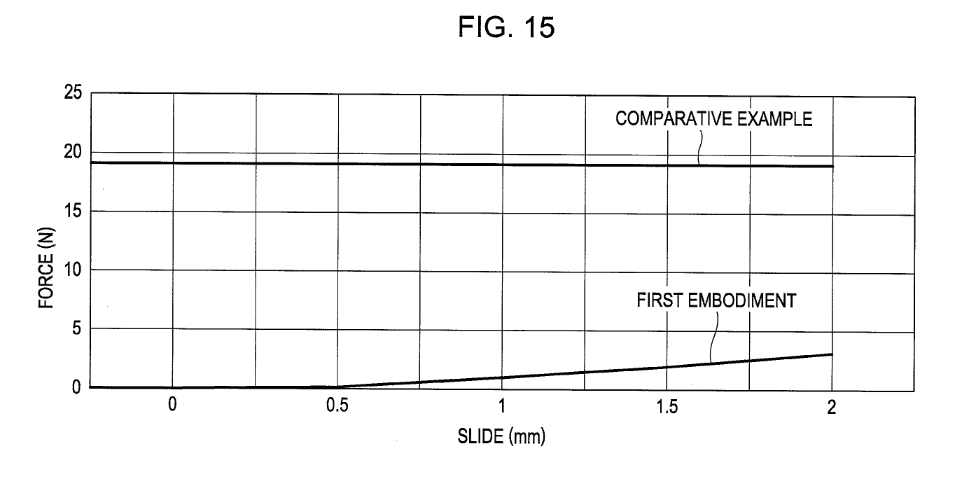

Next, an operational force applied to a cover in a comparative example and an operational force applied to the cover 500 in the first embodiment will be described with reference to FIG. 15.

FIG. 15 is a graph representing an operational force applied to the cover in the comparative example and an operational force applied to the seal part 590 in the first embodiment. The graph represents the amount of slide of the cover 500 on the horizontal axis; the origin (0 mm) of the graph represents the amount of slide of the cover 500 when the seal part 590 has reached the first projection 226 and second projection 227, and the end point (2 mm) of the graph represents the amount of slide of the cover 500 when the joint end 560 of the cover 500 has abutted the joining wall 223a of the decorated part 223. Accordingly, the left side of the graph is an area that extends until the seal part 590 reaches the first projection 226 and second projection 227. To simplify the description that follows, the second projection 227 is omitted in the drawing.

The cover in the comparative example is formed by attaching a gasket to the cover 500 in the first embodiment. The cover is assumed to be waterproof to 1.5 m. The gasket, which is made of a silicone resin, has a frictional coefficient of about 0.42 (with respect to PC-ABC). The gasket is compressed by about 0.25 mm during its usage. In the comparative example, therefore, the cover is slid with the gasket compressed by 0.25 mm.

As illustrated in FIG. 15, the operational force applied to the cover in the comparative example does not almost change but remains at about 19 N from when the cover is started to be attached until the cover has been attached. That is, to obtain a waterproof level of 1.5 m with the cover in the comparative example, an operational force of about 19 N is required all the way from when the cover is started to be attached until the cover has been attached.

By contrast, the operational force applied to the cover 500 in the first embodiment is almost 0 N for a while after the attachment of the cover 500 has started. After the seal part 590 has reached the first projection 226 and second projection 227, the operational force applied to the cover 500 increases as the amount of slide of the cover 500 increases. However, even when the amount of slide of the cover 500 has reached 2 mm, the operational force remains at about 3 N.

As described above, in the first embodiment, the cover 500 can be slid without having to apply almost no operational force until the elastic film 593 of the seal part 590 reaches the first projection 226 and second projection 227. The operational force applied to the cover 500 is gradually increased from when the elastic film 593 of the seal part 590 has reached the first projection 226 and second projection 227 until the joint end 560 of the cover 500 abuts the joining wall 223a of the decorated part 223. Therefore, if a small operational force is applied while the cover 500 is being slid, the cover 500 can be continued to be slid. Furthermore, even immediately before the joint end 560 of the cover 500 abuts the joining wall 223a of the decorated part 223, only a small operational force is required as illustrated in FIG. 15. Since the operational force applied to the cover 500 is small as described above, it is suppressed that the cover 500 is incorrectly attached or comes off.

In this embodiment, the elastic film 593 of the seal part 590 has not come into contact with the lower case 200, specifically, with the pressurized wall part 225 until the elastic film 593 has reached the first projection 226 and second projection 227. However, the present disclosure is not limited to this; for example, the elastic film 593 may come into contact with the lower case 200.

In this embodiment, the first projection 226 and second projection 227 have been formed on the external case 220. However, the present disclosure is not limited to this; for example, only one of the first projection 226 and second projection 227 may be formed. Furthermore, a third projection parallel to the third wall 224c and a fourth projection 224d parallel to the fourth wall may be formed besides the first projection 226 and second projection 227.

Although the pressurized wall part 225 in this embodiment is a plane area formed in the lower case 200, this is not a limitation; for example, a rectangular ring-shaped plate member may be pasted to the external case 220 and the surface of the plate member may be used as the pressurized wall part 225. The surface of the pressurized wall part 225 may be coated with a resin or the like to reduce the coarseness of the surface of the pressurized wall part 225. If the coarseness of the surface of the pressurized wall part 225 is reduced, when the cover 500 is attached to the cover attaching part 222, the seal part 590 and pressurized wall part 225 are mutually placed in tight contact and a clearance therebetween is reduced, so high waterproof and dustproof levels can be obtained.

Although the seal part 590 in this embodiment is used to have the pressurized wall part 225 press the elastic film 593, the present disclosure is not limited to this; for example, a non-elastic film may be used instead of the elastic film 593, if the non-elastic film is flexible.

Variation

Although the annular space S below seal part 590 in the first embodiment has been filled with air, the embodiment is not limited to this; for example, a liquid such as water may be used instead of air if the liquid can uniformly increase the internal pressure of the annular space S over the entire length of the seal part 590 when the first projection 226 and second projection 227 are pressed against the seal part 590. If the annular space S is filled with a liquid, however, the elastic film 593 must be made of a liquid-impermeable material. Furthermore, isotropic gel may be used instead of air or a liquid. Since isotropic gel materials are easier to handle than liquids, they can simplify the manufacturing of the seal part 590. An isotopic gel material that uses silicon as the main raw material may be used, for example. In this embodiment, gel is defined to be one of fluids.

### Second Embodiment

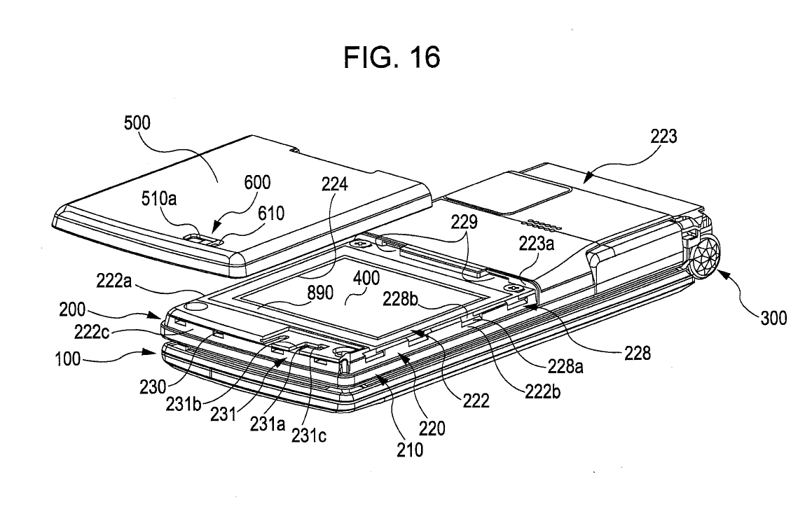

Next, a second embodiment will be described with reference to FIGS. 16 to 19.

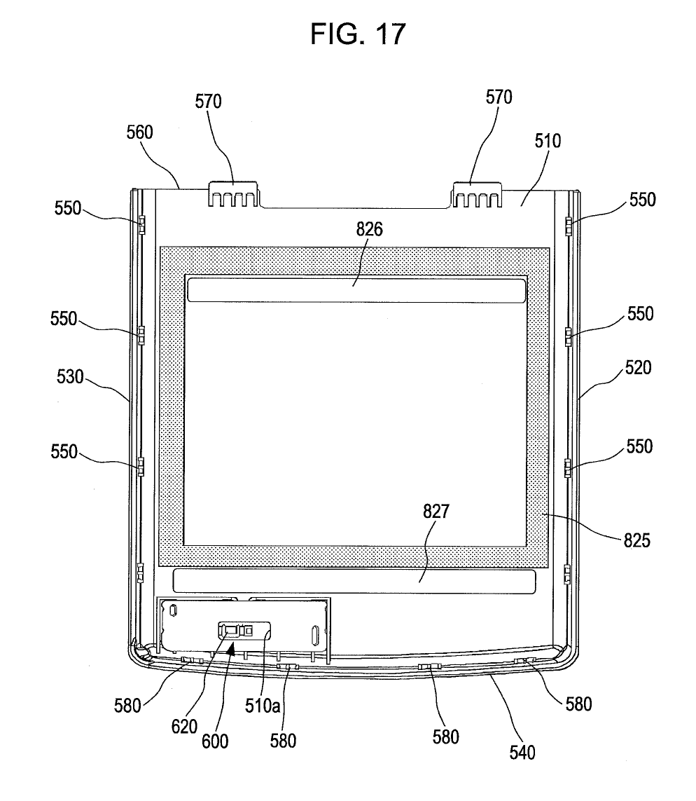

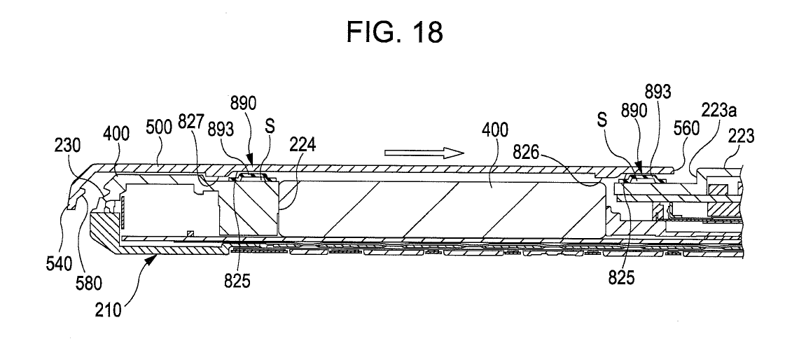

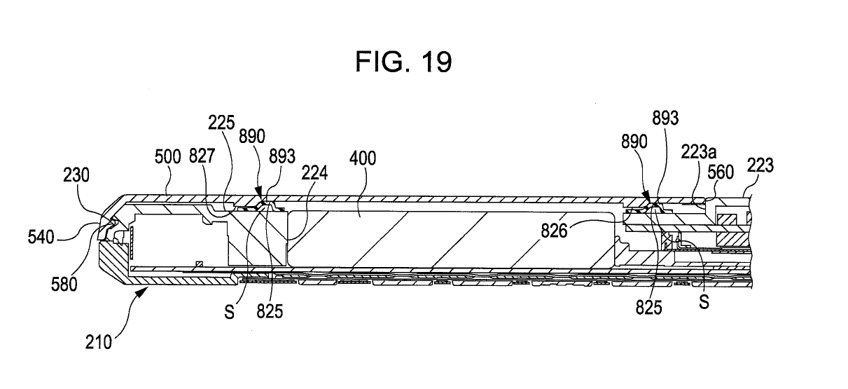

FIG. 16 is an exploded perspective view in which the cover 500 is removed from the lower case 200 in the second embodiment. FIG. 17 is an internal view of the cover 500 in the second embodiment. FIG. 18 is a cross sectional view of the lower case 200 when the cover 500 in the second embodiment starts to be attached. FIG. 19 is a cross sectional view of the lower case 200 when the cover 500 in the second embodiment has been attached.

In the first embodiment, the seal part 590 has been formed on the cover 500 and the first projection 226 and second projection 227 have been formed on the lower case 200. By contrast, in the second embodiment, a first projection 826 and a second projection 827 are formed on the cover 500 and a seal part 890 is formed on the lower case 200, as illustrated in FIGS. 16 and 17. A pressurized wall part 825 pressed by the seal part 890 is disposed on the inner surface of the cover 500, as indicated by the shaded area in FIG. 17.

The first projection 826 and second projection 827 are located at positions at which they do not interfere with the seal part 890 when the sliding claw 550 of the cover 500 is located in the second groove 228b of the guide groove 228. When the cover 500 is moved toward the hinge 300, the first projection 826 and second projection 827 are located at positions at which they interfere with the seal part 890. Accordingly, when the cover 500 is brought close to the cover attaching part 222, the seal part 890 does not come into contact with the first projection 826 and second projection 827, but the first projection 826 and second projection 827 come into contact with the seal part 890 in course of the movement of the cover 500 toward the hinge 300.

As described above, even if the positional relation between the seal part 890 and the first and second projections 826 and 827 is opposite to the positional relation in the first embodiment between the seal part 590 and the first and second projections 226 and 227, the operational force applied to the cover 500 can be reduced.

Since the cover 500 has lower stiffness than the lower case 200, the cover 500 may be deformed by being pressed by the seal part 890 when the cover 500 is attached. If, however, the first projection 826 and second projection 827 are formed on the cover 500 as in the second embodiment, the first projection 826 and second projection 827 are operable as ribs, increasing the stiffness of the cover 500. Accordingly, the deformation of the cover 500 due to the pressure of the seal part 890 is suppressed. Then, even if the seal part 890 presses the pressurized wall part 825, the cover 500 is not easily separated from the lower case 200, that is, the cover 500 does not easily come off the lower case 200, so the airtightness between the seal part 890 and the pressurized wall part 825 is reliably assured.

### Third Embodiment

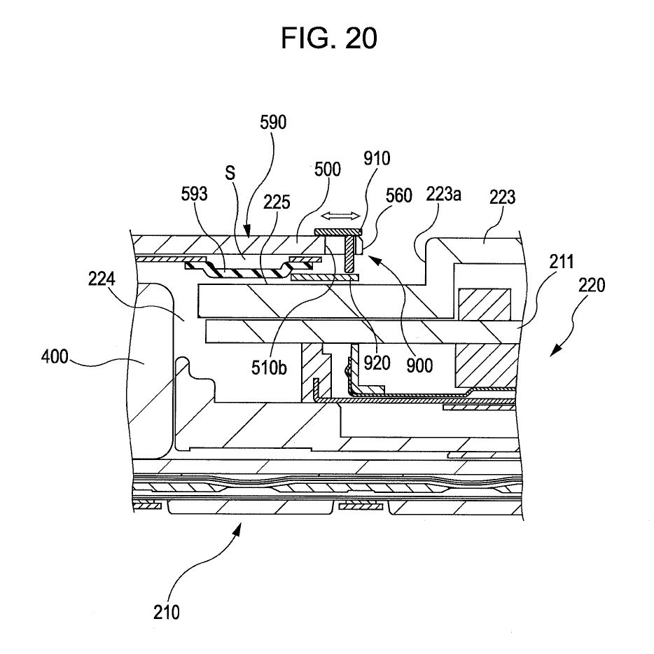

Next, a third embodiment will be described with reference to FIG. 20.

FIG. 20 is a partial cross sectional view of the lower case 200 in the third embodiment.

With the mobile telephone in the first embodiment, the first projection 226 and second projection 227 formed on the lower case 200 have been used to press the seal part 590. With a mobile telephone in the third embodiment, however, a pressing mechanism 900 is provided on the cover 500, instead of first and second projections, to press the elastic film 593 of the seal part 590.

As illustrated in FIG. 20, the pressing mechanism 900 is disposed in an elongated hole 510b formed in the cover 500 so as to be movable in the longitudinal direction of the elongated hole 510b. The pressing mechanism 900 has an operation strip 910 disposed outside the cover 500 and a pressing strip 920 disposed inside the cover 500.

The pressing mechanism 900 is disposed so that the seal part 890 is positioned ahead of the movement direction of the pressing strip 920 when the cover 500 is attached to the cover attaching part 222. When the operation strip 910 is moved in the longitudinal direction of the elongated hole 510b, therefore, the pressing strip 920 disposed inside the cover 500 is moved together, laterally pressing the elastic film 893 of the seal part 890.

As described above, even if the pressing mechanism 900 is used instead of the first projection 226 and second projection 227, the operational force applied to the cover 500 can be reduced. The pressing mechanism 900 in this embodiment is preferably disposed outside the seal part 890 of the cover 500. If the pressing mechanism 900 is disposed outside the seal part 890, the elongated hole 510b formed in the cover 500 is also formed outside the seal part 890, so the airtightness in the internal area of the seal part 890 is not lost.

Although the pressing mechanism 900 in the third embodiment is disposed on the cover 500, the present disclosure is not limited to this; for example, the pressing mechanism 900 may be disposed on the lower case 200.

Although the pressing mechanism 900 in the third embodiment is used instead of the first projection 226 and second projection 227 in the first embodiment, the present disclosure is not limited to this; for example, the pressing mechanism 900 in the third embodiment may be used instead of the first projection 826 and second projection 827 in the second embodiment.

Furthermore, the pressing mechanism 900 may be used together with the lock operation part 600. Specifically, the pressing strip 920 of the pressing mechanism 900 may be linked to the lock operation part 600, and the pressing strip 920 may press the seal part 890 in synchronization with the operation of the lock operation part 600.

So far, the mobile telephone has been described in the first to third embodiments, but the present disclosure is not limited to the mobile telephone. The present disclosure can also be applied to, for example, PDAs, notebook PCs, IC recorders, and any other electronic devices that need to be waterproof and dustproof.

Although the seal part 590 in the first embodiment and the seal part 890 in the second and third embodiments have had the annular space S between the cover 500 and the elastic film 593 or between the cover 500 and the elastic film 893 to include a liquid therein, this is not a limitation; for example, an annular elastic tube may be attached to the cover 500 or external case 220, instead of using the seal part 590 or seal part 890.

Although, in the first to third embodiments, the battery case 224 in which to install the battery pack 400 have been intended to be waterproof and dustproof, the present disclosure is not limited to this; for example, a storage portion in which to store a memory card such as an SD card or an accommodating section in which to accommodate external terminals may be intended to be waterproof and dustproof.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a case having an opening;
an electronic part mounted in the case;
a cover detachably attached to the case to close the opening;
an annular seal part disposed on one of the case and the cover, the seal part being positioned between the case and the cover to enclose the opening, the seal part being filled with a liquid; and
a pressing part that presses the seal part in a first direction parallel to a closing surface of the cover to expand the seal part in a second direction intersecting the closing surface of the cover so that the seal part presses another of the case and the cover.

2. The electronic device according to claim 1, wherein
the seal part is disposed on the cover, and
the pressing part is disposed on the case.

3. The electronic device according to claim 2, wherein the seal part includes a membranous member secured to the cover and having a space between the seal part and the cover, the space being filled with the liquid.

4. The electronic device according to claim 3, wherein the membranous member is formed with an elastic material.

5. The electronic device according to claim 2, wherein
the cover is slidably disposed on the case, and
the pressing part is located at a position at which the pressing part abuts the seal part when the cover slides on the case toward a position at which the cover closes the opening.

6. The electronic device according to claim 3, wherein
the cover is slidably disposed on the case, and
the pressing part is located at a position at which the pressing part abuts the seal part when the cover slides on the case toward a position at which the cover closes the opening.

7. The electronic device according to claim 4, wherein
the cover is slidably disposed on the case, and
the pressing part is located at a position at which the pressing part abuts the seal part when the cover slides on the case toward a position at which the cover closes the opening.

8. The electronic device according to claim 1, wherein
the seal part is disposed on the case, and
the pressing part is disposed on the cover.

9. The electronic device according to claim 8, wherein the seal part includes a membranous member secured to the case and having a space between the seal part and the case, the space being filled with the liquid.

10. The electronic device according to claim 9, wherein the membranous member is formed with an elastic material.

11. The electronic device according to claim 8, wherein
the cover is slidably disposed on the case, and
the pressing part is located at a position at which the pressing part abuts the seal part when the cover slides on the case toward a position at which the cover closes the opening.

12. The electronic device according to claim 9, wherein
the cover is slidably disposed on the case, and
the pressing part is located at a position at which the pressing part abuts the seal part when the cover slides on the case toward a position at which the cover closes the opening.

13. The electronic device according to claim 10, wherein
the cover is slidably disposed on the case, and
the pressing part is located at a position at which the pressing part abuts the seal part when the cover slides on the case toward a position at which the cover closes the opening.

14. The electronic device according to claim 1, wherein the liquid is a gas or a gel.
